(19) United States
(12) Patent Application Publication
(10) Pub. No.: US 2015/0050115 A1
(43) Pub. Date: Feb. 19, 2015

(54) ELECTRONIC EQUIPMENT HOUSING, HOUSING WORKBENCH AND DRAWING METHOD

(71) Applicant: FUJITSU LIMITED, Kawasaki-shi (JP)

(72) Inventor: Kazushige Kobayakawa, Kawasaki (JP)

(73) Assignee: FUJITSU LIMITED, Kawasaki-shi (JP)

(21) Appl. No.: 14/273,904

(22) Filed: May 9, 2014

(30) Foreign Application Priority Data
Aug. 15, 2013 (JP) 2013-168927

(51) Int. Cl. H05K 5/02; B25H 1/16

(52) U.S. Cl. CPC H05K 5/0217; B25H 1/16
USPC 414/800; 312/223.1; 312/306; 108/42

(57) ABSTRACT

An electronic equipment housing includes: a housing including a housing space that houses an electronic equipment and a workbench; and a first support provided in the housing, wherein the workbench includes: a base detachably attached to the first support; a placing plate, liftably coupled to the base, configured to place the electronic equipment on a placing surface; and a lifting mechanism configured to move the placing plate with respect to the base.

### CROSS-REFERENCE TO RELATED APPLICATION

This application is based upon and claims the benefit of priority of the prior Japanese Patent Application No. 2013-168927, filed on Aug. 15, 2013, the entire contents of which are incorporated herein by reference.

### FIELD

Embodiments discussed herein are related to an electronic equipment housing, a housing workbench, and a drawing method.

### BACKGROUND

An electronic equipment housing (also referred to below as an “electronic equipment rack” or simply a “rack”) houses electronic equipment such as a server computer. The rack has four columns and top and bottom plates. The left and right sides are covered with side plates, and the front and rear, which are openings, are covered with doors or the like.

Japanese Laid-open Patent Publication No. 2002-76659 discusses related art.

### SUMMARY

According to one aspect of the embodiments, an electronic equipment housing includes: a housing including a housing space that houses an electronic equipment and a workbench; and a first support provided in the housing, wherein the workbench includes: a base detachably attached to the first support; a placing plate, liftably coupled to the base, configured to place the electronic equipment on a placing surface; and a lifting mechanism configured to move the placing plate with respect to the base.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a rack;

FIG. 2 illustrates an example of a perspective view of an electronic equipment rack;

FIG. 3 illustrates an example of an exploded view of the rack;

FIG. 4 illustrates an example of a front view of the rack;

FIGS. 5A to 5D illustrate an example of a workbench;

FIG. 6 illustrates an example of a support;

FIGS. 7A to 7D illustrate an example of maintenance and inspection operation for an electronic equipment housed in a rack;

FIG. 8 illustrates an example of an exploded view of the rack; and

FIG. 9 illustrates an example of a rack with a workbench.

### DESCRIPTION OF EMBODIMENTS

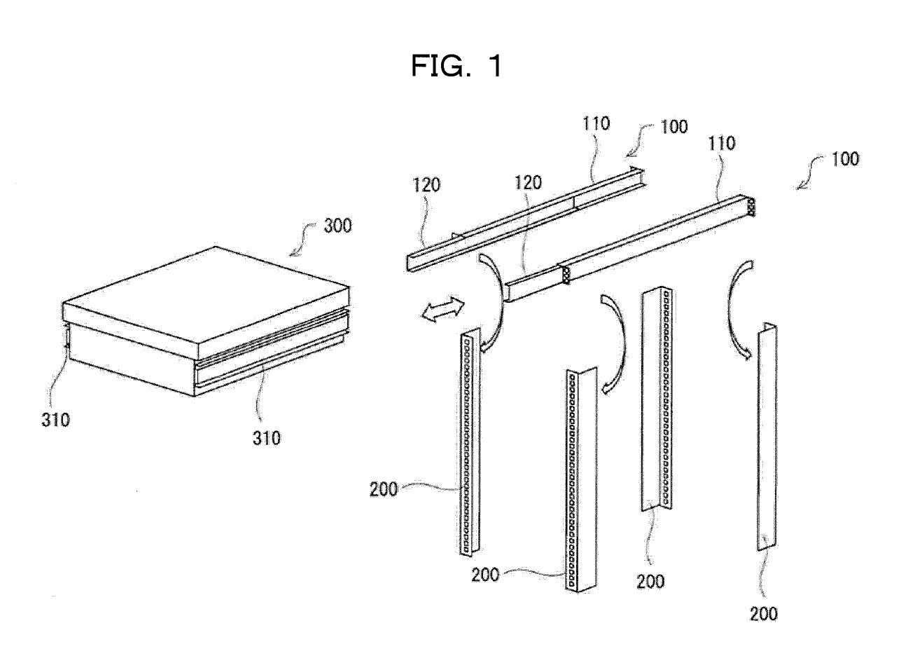

When maintenance and inspection are performed for electronic equipment housed in a rack, the electronic equipment is temporarily removed to the outside of the rack. FIG. 1 illustrates an example of a rack. Slide rails 100 illustrated in FIG. 1 are used to house the electronic equipment at a predetermined location in the rack. For example, columns 200 are erected at the four corners of the rack, and the slide rails 100 include guide rails 110 laid horizontally between the front and rear columns on the left side and between the front and rear columns on the right side, and telescoping rails 120 slidable back and forth along the guide rails 110. The telescoping rails 120 are fixed to fixed rails 310 fixed on the left and right sides of electronic equipment 300. When these slide rails 100 are used, the electronic equipment 300 is drawn from the rack by sliding the telescoping rails 120 along the guide rails 110 for the maintenance and inspection of the electronic equipment 300.

For example, when the slide rails 100 are used, the fixed rails 310 are installed on the left and right sides of the electronic equipment 300 as illustrated in FIG. 1. Therefore, the effective width of the electronic equipment 300 may not be ensured sufficiently.

For example, a rail member having a supporting surface that supports the bottom of the electronic equipment may be laid horizontally between the columns without the use of the slide rails. When the bottom of the electronic equipment is supported using this type of rail member, the above fixed rails may not be installed on the sides of the electronic equipment. The effective width of the electronic equipment may therefore be ensured. When the electronic equipment is removed from the rack temporarily for maintenance and inspection or the like, the electronic equipment is removed from the rack using a lifter or the like, for example, and the electronic equipment is placed on a floor, workbench, or the like. Then, the maintenance and inspection work is performed. Accordingly, the transfer pathway of the electronic equipment may become long, and downtime in operation of the electronic equipment may be prolonged. When the electronic equipment is removed from the rack, preparations for the maintenance and inspection may be extensive, and an amount of work for the maintenance and inspection may be increased.

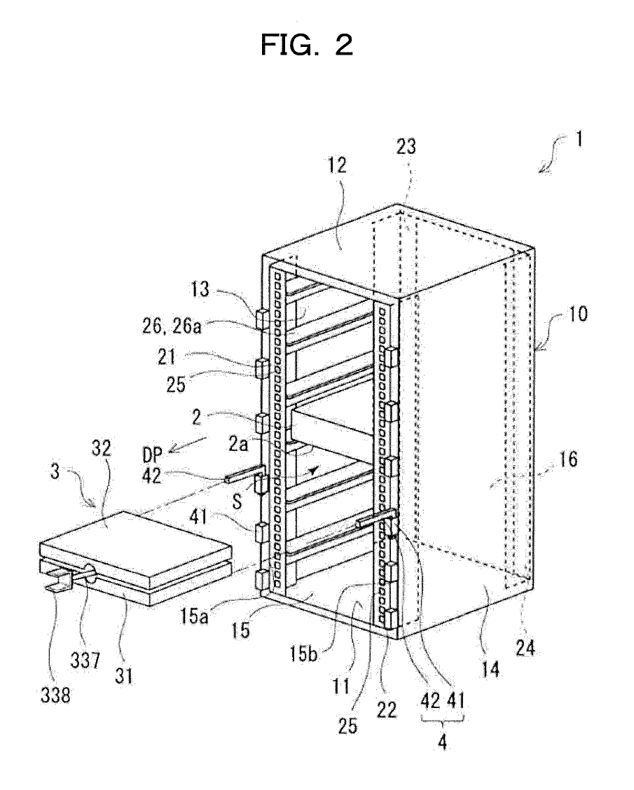

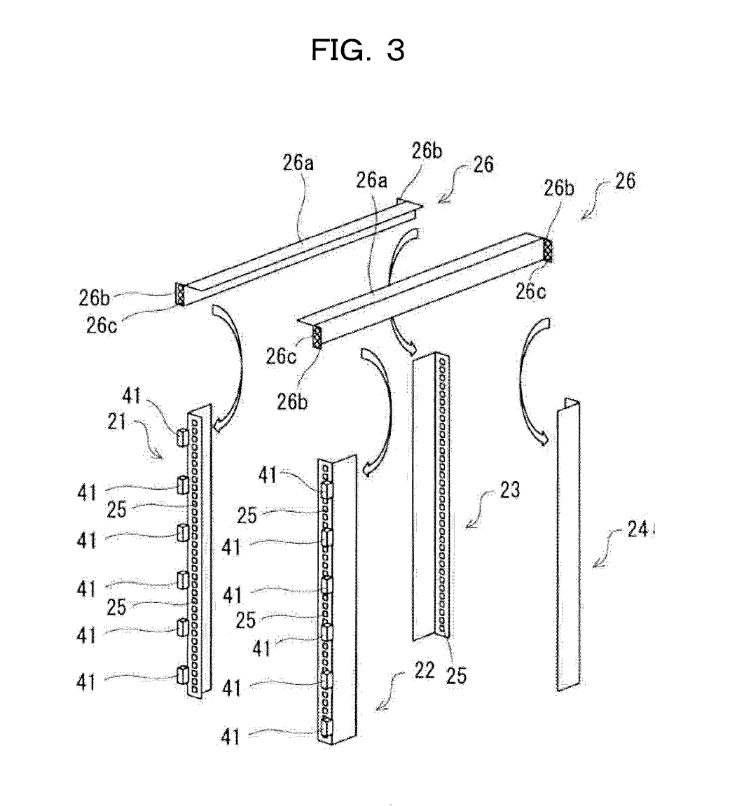

FIG. 2 illustrates an example of a perspective view of an electronic equipment rack. The electronic equipment rack illustrated in FIG. 2 may be an electronic equipment housing, and may be referred to as simply a “rack”. FIG. 3 illustrates an example of an exploded view of a rack. A rack 1 includes a rack body 10, which is a housing used to house (mount) electronic equipment 2 such as a server computer. The rack body 10 has a housing space S that may house a plurality of pieces of the electronic equipment 2 in upper and lower locations. The rack body 10 includes a bottom plate 11 laid on a floor, a top plate 12 spaced above from the bottom plate 11 and opposite to the bottom plate 11, and a pair of side plates 13 and 14 that couple the bottom plate 11 and the top plate 12. In the rack body 10, four columns 21 to 24 are erected along the vertical direction between the bottom plate 11 and the top plate 12. The columns 21 to 24 are disposed at the four corners of the plane of the rack body 10. The upper and lower ends of the columns 21 to 24 are fixed to the bottom plate 11 and the top plate 12, respectively.

As illustrated in FIG. 2, in the rack body 10, a front opening 15 and a rear opening 16 are formed such that the front opening 15 and the rear opening 16 are surrounded by the bottom plate 11, the top plate 12, and the pair of the side plates 13 and 14. In the rack 1 (rack body 10), the side on which the front opening 15 is located may be defined as a “front” and the side on which the rear opening 16 is located may be defined as a “rear”. In the rack 1 (rack body 10), the side on which the top plate 12 is located may be defined as a “top” and the side on which the bottom plate 11 is located may be defined as a “bottom”. In the rack 1 (rack body 10), the side on which the side plate 13 is located may be defined as a “left” and the side on which the side plate 14 is located may be defined as a “right”. The side plate 13 may be referred to as a “left side plate” and the side plate 14 may be referred to as a “right side plate”. The front opening 15 and the rear opening 16 may be provided with doors by which the front opening 15 and the rear opening 16 are openable and closable.

The columns 21 to 24 erected at the four corners of the rack body 10 may be referred to as a first column 21 to a fourth column 24. The first column 21 is erected near a left lateral edge 15a of the front opening 15 and a second column 22 is erected near a right lateral edge 15b of the front opening 15.

As illustrated in FIG. 3, installation holes 25 are provided at a certain intervals along the vertical direction in each of the first column 21 to the fourth column 24. The installation holes 25 are used to install rail members 26 to the first column 21 to the fourth column 24. The rail members 26 are laid horizontally between the first column 21 and a third column 23, and between the second column 22 and the fourth column 24. Each rail member 26 has an approximately L-shaped cross section orthogonal to the longitudinal direction and a supporting surface 26a that supports a bottom surface 2a of the electronic equipment 2. Flanges 26b are provided at both ends of each rail member 26 in the longitudinal direction, and installation holes 26c are formed on the flanges 26b.

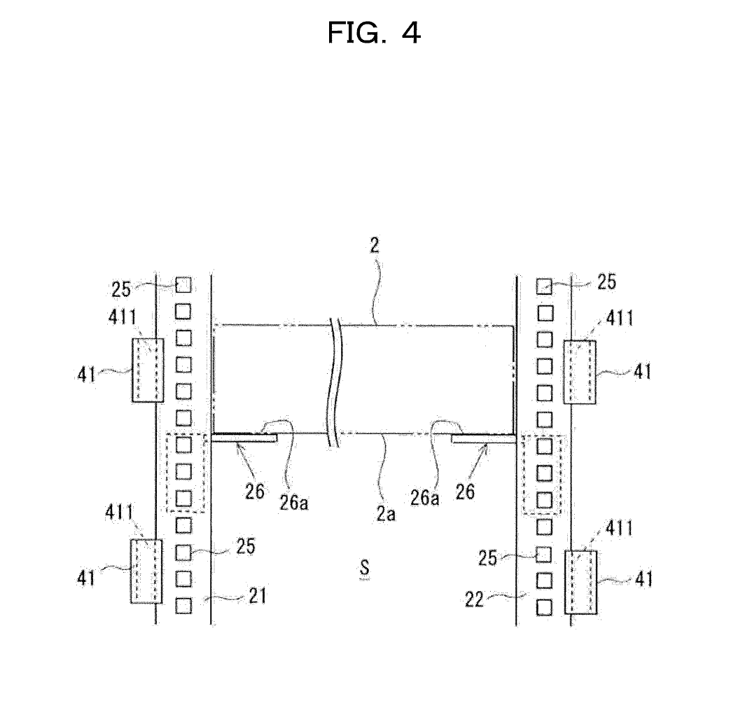

In FIG. 3, three installation holes 26c are provided side by side in each flange 26b of the rail members 26. Any number of installation holes 26c may be provided. The center-to-center distance between the installation holes 26c in the flanges 26b may be substantially the same as the center-to-center distance between the installation holes 25 in the first column 21 to the fourth column 24. The rail members 26 may be coupled to the first column 21 to the fourth column 24 with fasteners such as screws or nuts, for example. FIG. 4 illustrates an example of a front view of a rack. In the front view in FIG. 4, the electronic equipment 2 is placed on a pair of the rail members 26 laid horizontally in the columns 21 to 24. Since many installation holes 25 are equally spaced along the longitudinal direction in the first column 21 to the fourth column 24, the rail members 26 may be laid horizontally at any height in the rack body 10.

The rail members 26 are installed to the columns 21 to 24 so that the supporting surfaces 26a are in a horizontal position in the rack body 10. The lateral edges of the bottom surface 2a of the electronic equipment 2 is supported on the supporting surfaces 26a of the rail members 26 laid horizontally in the housing space S of the rack body 10, and the electronic equipment 2 is placed on the rail members 26. Accordingly, the electronic equipment 2 is housed at a predetermined location in the housing space S of the rack body 10.

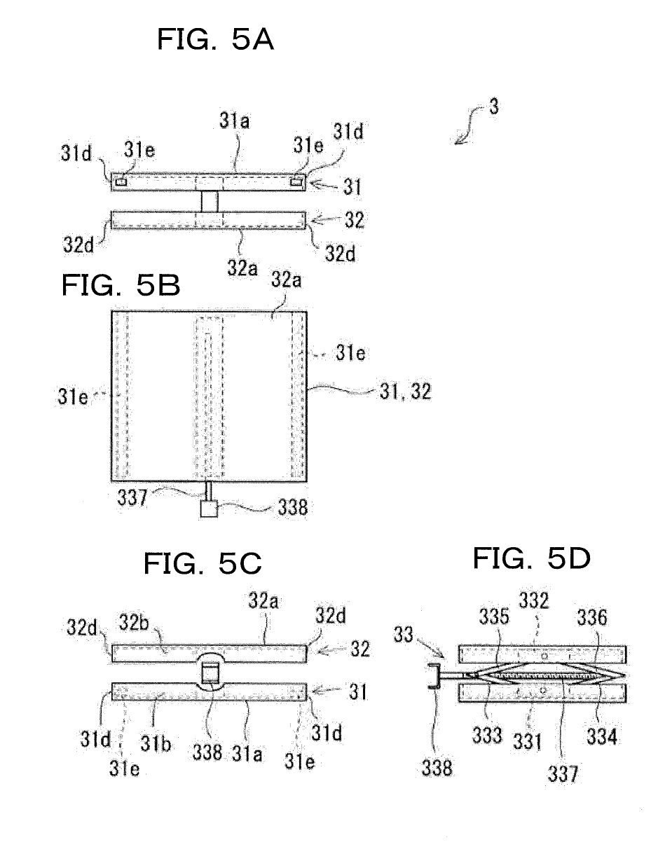

A housing workbench 3 provided in the rack 1 may be referred to below as a “workbench”, “work table”, or “maintenance table”. The workbench 3 is a bedplate used to take the electronic equipment 2 in and out of the housing space S of the rack 1 (rack body 10), and is detachably installed to the rack 1 (rack body 10). FIGS. 5A to 5D illustrate an example of a workbench. FIG. 5A is a top view of the workbench 3, FIG. 5B is a rear view of the workbench 3, FIG. 5C is a front view of the workbench 3, and FIG. 5D is a side view of the workbench 3. The workbench 3 is detachably installed to the rack 1 via supports 4, for example, a receiver 41 and an L-shaped retainer 42 provided in the rack body 10. The workbench 3 includes a base 31 detachably attached to the supports 4 provided in the rack body 10, a placing plate 32 liftably coupled to the base 31, and a lifting mechanism 33 that moves up and down the placing plate 32 with respect to the base 31.

As illustrated in FIGS. 5A to 5D, the base 31 of the workbench 3 has a bottom surface 31a in a rectangular shape, a front plate 31b erected from the bottom surface 31a, a rear plate 31c, and a pair of side plates 31d. A pedestal 331 of the lifting mechanism 33 is fixed to the inner side of the bottom surface 31a of the base 31. The placing plate 32 of the workbench 3 includes placing surface 32a in a rectangular shape, a front plate 32b erected from the placing surface 32a, a rear plate 32c, and a pair of side plates 32d. A pedestal 332 of the lifting mechanism 33 is fixed to the inner side of the placing surface 32a of the placing plate 32.

The lifting mechanism 33 may be a pantograph-type jack. The lifting mechanism 33 includes, for example, the pedestals 331, 332, a pair of lower arms 333, 334, a pair of upper arms 335, 336, a screw member 337, and a handle 338. One end of each of the pair of the lower arms 333, 334 is swingably coupled to the pedestal 331. One end of each of the pair of the upper arms 335, 336 is swingably coupled to the pedestal 332. The other ends of the pair of the lower arms 333, 334 and the pair of the upper arms 335, 336 are swingably coupled to each other via coupling shafts. A pantograph-type jack of related art may be used. When the handle 338 is manipulated to rotate the screw member 337 in one direction, the upper arms 335, 336 and the lower arms 333, 334 rise. Therefore, the pedestal 332 installed on the placing plate 32 moves away from the pedestal 331 installed on the base 31 of the workbench 3, and the placing plate 32 (placing surface 32a) goes up with respect to the base 31. When the handle 338 is manipulated to rotate the screw member 337 in the opposite direction, the upper arms 335, 336 and the lower arms 333, 334 fall gradually to a horizontal position. Therefore, the placing plate 32 (placing surface 32a) goes down with respect to the base 31.

Notches are formed in the front plate 31b of the base 31 of the lifting mechanism 33 and the front plate 32b of the placing plate 32, and the screw member 337 and the front plates 31b, 32b may not interfere with each other while the placing plate 32 is going down to the base 31. The base 31 has a pair of insertion holes 31e formed along the front-back direction in the base 31. The pair of the insertion holes 31e are located near the pair of the side plates 31d and have openings to the rear plate 31c of the base 31.

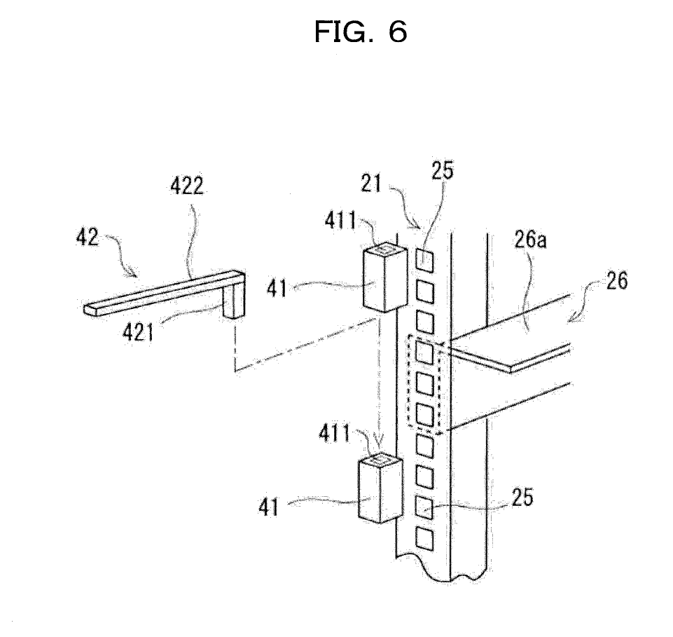

FIG. 6 illustrates an example of a support. The supports 4 support and fix the workbench 3 to the rack body 10. The supports 4 include the receivers 41 set in the first column 21 and the second column 22 erected on the left and right of the front opening 15 of the rack body 10, and the L-shaped retainers 42 detachably attached to the receivers 41. The receivers 41 may be fixed parts, and the L-shaped retainers 42 may be installation members. As illustrated in FIG. 6, each L-shaped retainer 42 is a member having an approximately L shape in a planar view, and has an attaching part 421 and a supporting part 422 that are orthogonal to each other. The L-shaped retainers 42 are formed of metal, for example.

The receivers 41 are provided in the first column 21 and the second column 22, and each receiver 42 is formed as a tubular member having an attaching hole 411 to which the attaching part 421 of the L-shaped retainer 42 is detachably attached. The shape of the attaching holes 411 of the receivers 41 corresponds to the shape of the attaching parts 421 of the L-shaped retainers 42, and the attaching holes 411 may be, for example, quadrilateral in cross-sectional shape. Any shape of the attaching parts 421 of the L-shaped retainers 42 and any shape of the attaching holes 411 of the receivers 41 may be used.

The attaching holes 411 of the receivers 41 extend along the height direction (vertical direction) in the rack body 10, for example, the vertical direction (longitudinal direction) in the first column 21 and the second column 22 erected in the housing space S of the rack body 10. The receivers 41 are provided at a plurality of places and equally spaced along the vertical direction in the first column 21 and the second column 22. As illustrated in FIGS. 2 to 4, the receivers 41 are provided in a pair at places of substantially the same height in the first column 21 and the second column 22. By inserting the attaching parts 421 of the L-shaped retainers 42 into the attaching holes 411 of the receivers 41, the L-shaped retainers 42 are attached to the receivers 41. The supporting parts 422 of the L-shaped retainers 42 are insertable into the insertion holes 31e formed in the base 31 of the workbench 3. By inserting the supporting parts 422 of the L-shaped retainers 42 attached to the receivers 41 into the insertion holes 31e formed in the base 31 of the workbench 3, the workbench 3 is attached to the rack body 10.

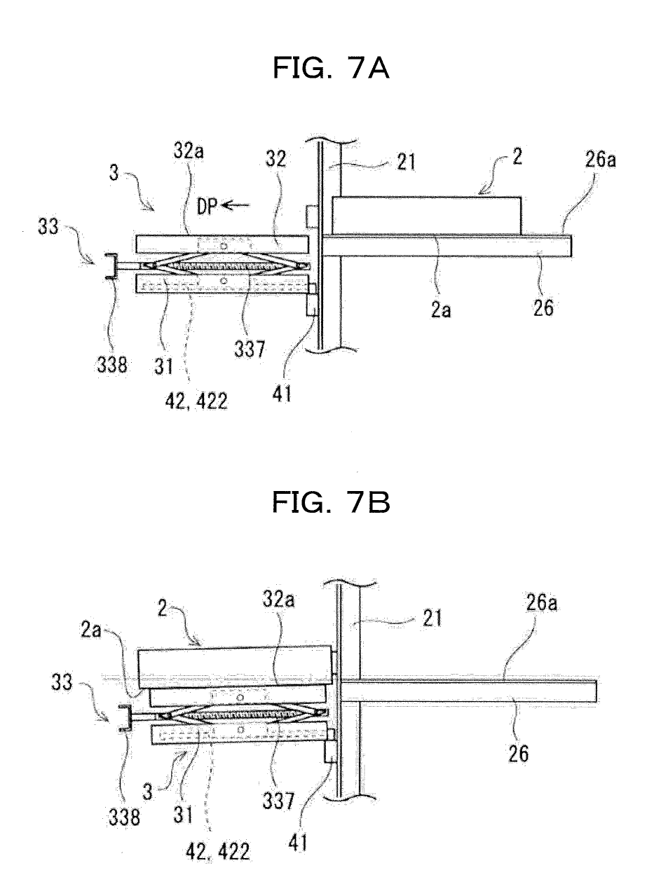

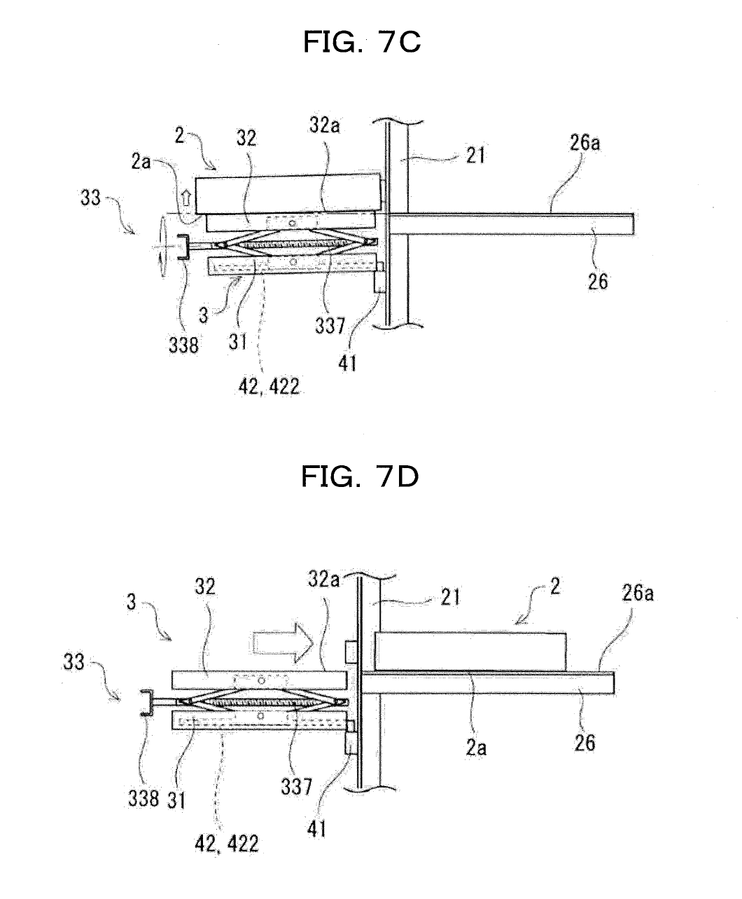

In the rack 1, when maintenance and inspection work is performed for the electronic equipment 2 housed in the housing space S of the rack body 10, the workbench 3 is attached to the front side of the rack body 10 (see FIG. 2). FIGS. 7A to 7D illustrate an example of a maintenance and inspection operation for an electronic equipment housed in a rack. In FIGS. 7A to 7D, the electronic equipment 2 housed in the housing space S of the rack body 10 is drawn to the workbench 3, the maintenance and inspection operation is performed, and then the electronic equipment 2 is housed in the housing space S again.

For the maintenance and inspection operation, the L-shaped retainers 42 are attached to a pair of the receivers 41 for the electronic equipment 2 to be drawn from the housing space S. The pair of the receivers 41 may be a pair of receivers provided at substantially the same height in the first column 21 and the second column 22 erected on the lateral edges 15a, 15b on both sides of the front opening 15. By inserting the attaching parts 421 of the L-shaped retainers 42 into the attaching holes 411 of the receivers 41, the L-shaped retainers 42 are attached to the receivers 41. The supporting parts 422 of the pair of the L-shaped retainers 42 are inserted into the left and right insertion holes 31e of the base 31 of the workbench 3. As a result, the workbench 3 is attached to the rack body 10 via the pair of the supports 4 including the receivers 41 and the L-shaped retainers 42 as illustrated in FIG. 7A.

The electronic equipment 2 is slid over and along the supporting surfaces 26a of the rail members 26. The direction in which the electronic equipment 2 housed in the housing space S is drawn from the front opening 15 for the maintenance and inspection operation is referred to as a “drawing direction DP”. The rail members 26 are laid horizontally along the drawing direction DP. As illustrated in FIG. 7A, an operator slides the electronic equipment 2 over the supporting surfaces 26a of the rail members 26 along the drawing direction DP to draw the electronic equipment 2 from within the housing space S to the placing surface 32a of the placing plate 32 of the workbench 3. In the rack 1, the workbench 3 is attached to or detached from the rack 1 via the supports 4, and therefore the electronic equipment 2 may not be removed from the rack 1 when the maintenance and inspection operation is performed. Since the electronic equipment 2 to be inspected is easily drawn simply by installing the workbench 3 at the height corresponding to the electronic equipment 2, convenience for the operator may be improved. Since the electronic equipment 2 is not removed using a lifter or the like, the transfer pathway of the electronic equipment 2 may be shortened during the maintenance and inspection operation. Downtime in operation (running) of the electronic equipment 2 may be reduced. Since the electronic equipment 2 is drawn from the housing space S of the rack body 10 and then the maintenance and inspection operation is performed for the electronic equipment 2, an amount of work desired for the maintenance and inspection may be reduced.

When the electronic equipment 2 is placed on the placing surface 32a, the supporting parts 422 of the L-shaped retainers 42 may bend under due to the weight of the electronic equipment 2, causing the front edge side of the placing surface 32a to lower (see FIG. 7B). If the placing surface 32a of the placing plate 32 lowers (sinks) due to the weight of the electronic equipment 2, the height of the bottom surface 2a of the electronic equipment 2 may be lower than the supporting surfaces 26a of the rail members 26. Thus, it may become difficult to put the electronic equipment 2 back on the supporting surfaces 26a of the rail members 26, increasing an amount of work for housing the electronic equipment 2 in the housing space S.

The workbench 3 attached to the rack body 10 includes the placing plate 32 liftably coupled to the base 31, and the lifting mechanism 33 that moves up and down the placing plate 32 with respect to the base 31. If the front edge side of the placing surface 32a of the workbench 3 lowers due to the weight of the electronic equipment 2 drawn to the placing surface 32a, the handle 338 of the lifting mechanism 33 is manipulated to raise the placing plate 32 relatively from the base 31 (see FIG. 7C). The operator may easily raise the position of the bottom surface 2a of the electronic equipment 2 to the height corresponding to the supporting surfaces 26a of the rail members 26 in this manner. Accordingly, the electronic equipment 2 may be easily brought into and housed in the housing space S by sliding the bottom surface 2 of the electronic equipment 2 over the supporting surfaces 26a of the rail members 26 (see FIG. 7D).

In the rack 1, even if the slide rails are not used, the electronic equipment 2 is easily drawn to the workbench 3 without removing the electronic equipment 2 from the rack body 10, and then the maintenance and inspection operation is performed. When the maintenance and inspection operation for the electronic equipment 2 is completed and the electronic equipment 2 is to be housed in the housing space S, even if the height of the placing surface 32a of the workbench 3 lowers, the electronic equipment 2 may be easily housed in the housing space S with the lifting mechanism 33. Therefore, the operator may perform the maintenance and inspection operation for the electronic equipment 2 easily.

In the rack 1, since the rail members 26 having the supporting surfaces 26a that support the bottom surface 2a of the electronic equipment 2 are fixed to the rack body 10, the fixed rails for fixing the expandable rails of the slide rails may not be installed on the sides of the electronic equipment 2. Therefore, the horizontal width dimension of the electronic equipment 2 may be substantially the same as the horizontal width dimension of the front opening 15 formed between the first column 21 and the second column 22, as illustrated in FIG. 4. Accordingly, the horizontal width dimension of the electronic equipment 2 may be ensured largely up to the inside dimension between the first column 21 and the second column 22.

In the rack 1, the columns 21 to 24, in which to lay the rail members 26 horizontally, are erected at the four corners of the housing space S of the rack body 10; the rail members 26 are laid horizontally along the drawing direction DP in which the electronic equipment 2 is drawn from the housing space S. Therefore, when the electronic equipment 2 is drawn from the housing space S for the maintenance and inspection operation or the like, the bottom surface 2a of the electronic equipment 2 may slid in the drawing direction DP in which the electronic equipment 2 is drawn, along the longitudinal direction of the supporting surfaces 26a of the rail members 26. Accordingly, the electronic equipment 2 may be easily drawn from the housing space S of the rack body 10 to the outside.

In the rack 1, the receivers 41 of the supports 4 are provided at a plurality of places along the vertical direction (longitudinal direction) in the first column 21 and the second column 22 erected in the housing space S of the rack body 10. Therefore, the L-shaped retainers 42 are attached by selectively using the receivers 41 placed near the housing height of the electronic equipment 2 to be drawn from the housing space S of the rack body 10, and the workbench 3 is attached via the L-shaped retainers 42. Accordingly, when the electronic equipment 2 is drawn to the workbench 3, if the placing surface 32a lowers due to the weight of the electronic equipment 2, the handle 338 may be less manipulated to match the height of the placing surface 32a of the placing plate 32 with the supporting surfaces 26a of the rail members 26. For example, the height of the placing surface 32a may be matched with the height of the supporting surfaces 26a accurately and easily by fine-tuning the height of the placing plate 32 relative to the base 31 with the lifting mechanism 33. The rack 1 that increases convenience and further lightens workload for the operator may be provided.

The supports 4 include the receivers 41 set in the first column 21 and the second column 22 erected on the left and right of the front opening 15 of the rack body 10, and the L-shaped retainers 42 detachably attached to the receivers 41. The base 31 of the workbench 3 is supported by the L-shaped retainers 42 attached to the receivers 41. Therefore, when the operator performs the maintenance and inspection operation for the electronic equipment 2, the workbench 3 is attached via the L-shaped retainers 42 by selectively using a pair of the receivers 41 provided at the height corresponding to the electronic equipment 2 to be inspected. A pair of the L-shaped retainers 42 suffice regardless of the number of the set receivers 42, and a cost may be reduced.

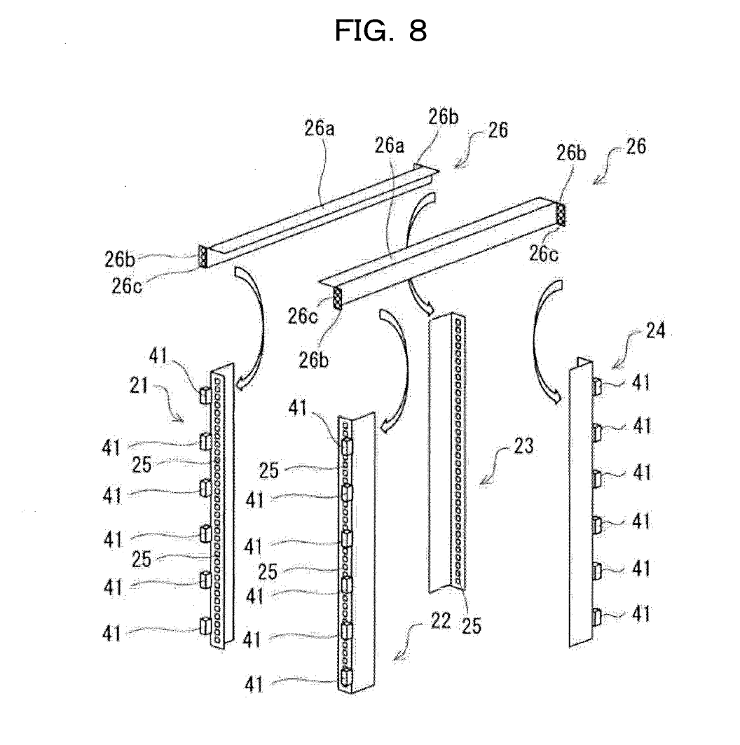

FIG. 8 illustrates an example of an exploded view of a rack. A plurality of the receivers 41 are provided along the vertical direction (longitudinal direction) in the third and fourth columns, in addition to the first column 21 and the second column 22. The height of each receiver 41 in the first column 21 to the fourth column 24 is substantially the same in each of the columns 21 to 24. The receivers 41 may be provided in the third column 23 illustrated in FIG. 8. The structure of the rack 1 and other components illustrated in FIG. 8 may be substantially the same as or similar to the structures illustrated in FIGS. 1 to 6.

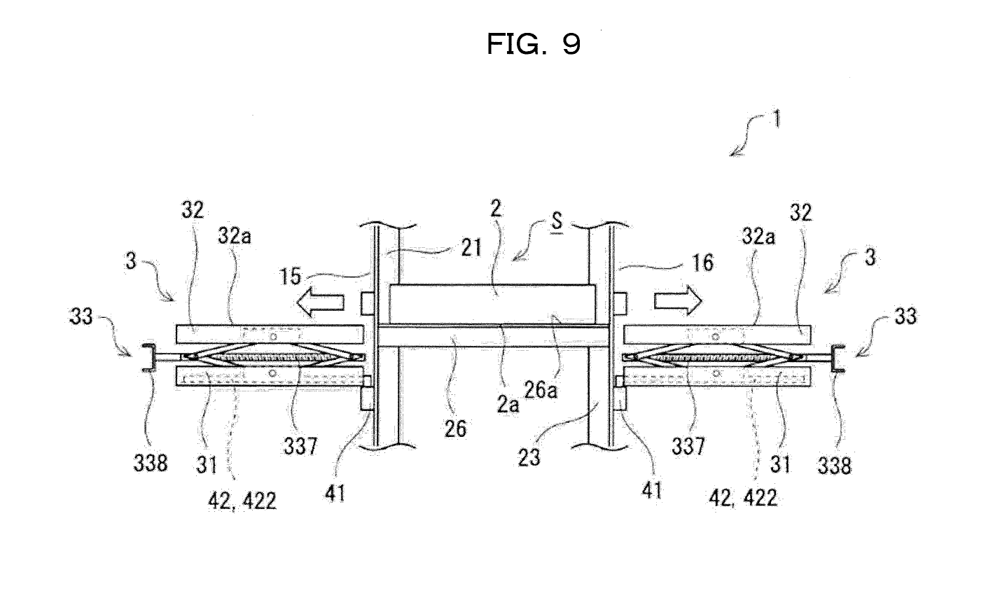

FIG. 9 illustrates an example of a rack with a workbench. In FIG. 9, the workbenches 3 are attached to both front and rear sides of the rack 1 illustrated in FIG. 8. In the rack 1, the receivers 41 are provided in the third column 23 and the fourth column 24 erected on the lateral edges on both sides of the rear opening 16, and therefore the workbench 3 may also be attached to the rear side of the rack 1 as illustrated in FIG. 9. The method of attaching the workbench 3 to the rear side of the rack 1 may be substantially the same as or similar to the method of attaching the workbench 3 to the front side of the rack 1. Since the electronic equipment 2 in the housing space S is drawn from any of the front opening 15 and the rear opening 16 of the rack 1 to the outside, the rack that increases convenience for the operator may be provided.

As the supports 4 used to attach the workbench 3 to the rack body 10, the receivers 41 installed in the rack body 10 and the L-shaped retainers 42 detachably attached to the receivers 41 may be adopted in combination. The supports 4 may be fixed to the rack body 10 in an integrated manner. As the lifting mechanism 33, a pantograph-type jack may be adopted, or another mechanism that moves up and down the placing plate 32 with respect to the base 31 of the workbench 3 may be adopted. The lifting mechanism 33 may be operated by manipulating the handle 338, or the lifting mechanism 33 may be operated by a motor or the like.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic equipment housing comprising:
a housing including a housing space that houses an electronic equipment and a workbench; and
a first support provided in the housing,
wherein the workbench includes:
a base detachably attached to the first support;
a placing plate, liftably coupled to the base, configured to place the electronic equipment on a placing surface; and
a lifting mechanism configured to move the placing plate with respect to the base.

2. The electronic equipment housing according to claim 1, comprising,
a rail member including a supporting surface that supports a bottom of the electronic equipment and fixed to the housing.

3. The electronic equipment housing according to claim 2, comprising,
columns, erected at four corners of the housing space, configured to lay the rail member horizontally in a drawing direction in which the electronic equipment is drawn from the housing space.

4. The electronic equipment housing according to claim 1, further comprising,
a plurality of second supports including the first support which are provided at a plurality of places along a vertical direction in columns erected in the housing space.

5. The electronic equipment housing according to claim 3,
wherein the first support includes a fixed part fixed to one of the columns and an installation member detachably attached to the fixed part, and the base is supported by the installation member attached to the fixed part.

6. The electronic equipment housing according to claim 5,
wherein the installation member is L-shaped.

7. The electronic equipment housing according to claim 1,
wherein the lifting mechanism includes a pantograph-type jack.

8. A housing workbench, comprising:
a base detachably attached to a first support provided in a housing including a housing space that houses an electronic equipment;
a placing plate, liftably coupled to the base, configured to place the electronic equipment on a placing surface; and
a lifting mechanism configured to move the placing plate with respect to the base.

9. The housing workbench according to claim 8,
wherein a rail member including a supporting surface that supports a bottom of the electronic equipment is fixed to the housing.

10. The housing workbench according to claim 9,
wherein columns are erected at four corners of the housing space to lay the rail member horizontally in a drawing direction in which the electronic equipment is drawn from the housing space.

11. The housing workbench according to claim 8,
wherein a plurality of second supports including the first support are provided at a plurality of places along a vertical direction in columns erected in the housing space.

12. The housing workbench according to claim 10,
wherein the first support includes a fixed part fixed to one of the columns and an installation member detachably attached to the fixed part, and the base is supported by the installation member attached to the fixed part.

13. The housing workbench according to claim 12,
wherein the installation member is L-shaped.

14. The housing workbench according to claim 8,
wherein the lifting mechanism includes a pantograph-type jack.

15. A drawing method comprising:
selecting, from a plurality of supports provided in a housing including a housing space that houses an electronic equipment, a first support that corresponds to a position of the electronic equipment to be drawn from the housing;
attaching a workbench to the housing via the first support; and
drawing the electronic equipment to a placing plate of the workbench via a rail member provided in the housing.

16. The drawing method according to claim 15, comprising,
moving the placing plate on which the electronic equipment is placed up and down to house the electronic equipment in the housing.
